(19) United States
(12) Patent Application Publication
(10) Pub. No.: US 2012/0280109 A1
(43) Pub. Date: Nov. 8, 2012

(54) METHOD, APPARATUS AND SYSTEM TO PROVIDE CONDUCTIVITY FOR A SUBSTRATE OF AN IMAGE SENSING PIXEL

(75) Inventors: Duli Mao, Sunnyvale, CA (US); Hsin-Chih Tai, San Jose, CA (US); Vincent Venezia, Los Gatos, CA (US); Keh-Chiang Ku, Cupertino, CA (US); Rongsheng Yang, San Jose, CA (US)

(73) Assignee: OMNIVISION TECHNOLOGIES, INC., Santa Clara, CA (US)

(21) Appl. No.: 13/101,991

(22) Filed: May 5, 2011

(51) Int. Cl. H01L 27/146; H01L 31/18

(52) U.S. Cl. 250/208.1; 257/292; 438/73; 257/E27.133; 257/E31.084

(57) ABSTRACT

Techniques for promoting conductivity in a substrate for a pixel array. In an embodiment, an isolation region and a dopant well are disposed within an epitaxial layer adjoining the substrate, where a portion of the dopant well is between the substrate and a portion of the isolation well. In another embodiment, a contact is further disposed within the epitaxial layer, where a portion of the isolation region surrounds a portion of the contact.

### BACKGROUND

1. Technical Field

This disclosure relates generally to image sensors, and in particular, but not exclusively to complementary metal-oxide semiconductor (“CMOS”) image sensors.

2. Background Art

FIG. 1 illustrates a pixel array structure, according to an existing technique, in which two neighboring CMOS image sensors (CIS) pixels 100 are formed within a p-type doped epitaxial (or “epi”) layer 140 disposed over a p-type doped silicon substrate 105. When a photo-generated charge carrier is formed shallow within pixel 100 (e.g., charge carrier 150), it experiences a strong upward attractive force (shown by the arrows 145) towards a photo-sensor or photodiode (“PD”) region 115, due to a depletion region or P-N junction between PD region 115 and the underlying p-type doped epi layer 140. In the illustrated embodiment, a p-type doped pinning layer 135 overlays PD regions 115 to passivate their surfaces. CIS pixels 100 are separated by isolation structures—e.g. Shallow Trench Isolation (STI) regions 160—which are disposed within p-type doped wells 130. CIS pixels 100 include pixel circuitry (not shown) disposed adjacent to PD region 115 within a P doped well (not shown). Such pixel circuitry may commence acquisition of an image charge within PD region 115 to reset the image charge accumulated within PD region 115, to ready CIS pixel 100 for the next image, or to transfer out the image data acquired by CIS pixel 100. When substrate 105 is made very thin, such as in the case of a Back Side Illuminated (BSI) CIS, and/or when the number of pixels is made very large, the lateral electrical resistance within substrate 105 may become relatively large and reduce performance of the pixel array. Performance limitations associated with increased substrate resistance are therefore problematic—particularly in BSI devices. Other thin substrate devices such as those fabricated on Silicon On Insulator (SOI) substrates or those incorporating buried collector layers may also have similar problems.

### BRIEF DESCRIPTION OF THE DRAWINGS

The various embodiments of the present invention are illustrated by way of example, and not by way of limitation, in the figures of the accompanying drawings and in which:

FIG. 1 is a block diagram showing features of a pixel array according to an existing technique.

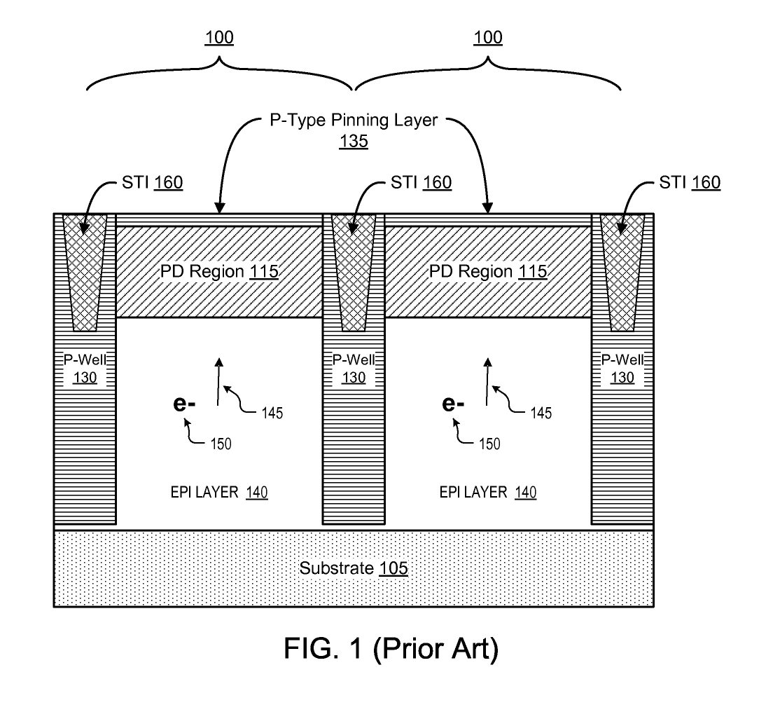

FIG. 2 is a block diagram illustrating features of an imaging system according to an embodiment.

FIG. 3 is a circuit diagram illustrating features of a pixel circuitry of two 4T pixels within an imaging system, in accordance with an embodiment.

FIG. 4 is block diagram showing both a surface elevation and a cross-sectional view of features in a pixel array structure according to an embodiment.

FIGS. 5A-5F are block diagrams illustrating cross-sectional views of a process for forming a pixel array structure in accordance with one embodiment.

FIG. 6 is a flow chart illustrating a process for operating a pixel array according to an embodiment.

### DETAILED DESCRIPTION

Certain embodiments provide techniques for promoting conductivity in a semiconductor substrate for a pixel array. The semiconductor substrate may adjoin an epitaxial layer in which (and/or onto which) is disposed one or more pixel structures of the pixel array. The substrate may, for example, be more heavily doped than the adjoining epitaxial layer.

An isolation region and a dopant well may each be disposed within the epitaxial layer. The isolation region may include a dielectric material such as silicon dioxide and/or any of a variety of other isolating materials for limiting electrical crosstalk. The dopant well may include a region more heavily doped than other regions of the epitaxial layer.

The isolation region may be located in a trench formed in a surface of the epitaxial layer. In certain embodiments, at least a portion of the dopant well may be disposed between the substrate and a portion of the isolation region. For example, a doping process may be performed to form the doping well at least between the substrate and the trench in which the isolation region is, or is to be, disposed. In an embodiment, the trench may be etched or otherwise formed after doping of the dopant well. The dopant well may additionally extend beyond a periphery of the isolation region in a direction parallel to the surface of the epitaxial layer. By way of illustration and not limitation, a portion of the dopant well may surround a portion of the isolation region—e.g. in the surface of the epitaxial layer and/or in some plane within the epitaxial layer.

In certain embodiments, a contact is also disposed within the epitaxial layer—e.g. in the same trench in which the isolation region is disposed. For example, a portion of the isolation region may form a cavity which extends through the isolation region. The cavity may expose or otherwise provide access to the dopant well—e.g. where a contact material may be disposed into the cavity and onto an underlying portion of the dopant well to provide a conductive channel between the dopant well and the surface of the epitaxial layer. The contact may be disposed in the trench—e.g. where the isolation region surrounds the contact within the trench. The contact may also extend in the cavity from the dopant well to the surface of the epitaxial layer, where the contact is available for coupling to a trace or other structure for drawing current from the substrate through the dopant well and the contact.

In an embodiment, a portion of the isolation region may surround a portion of the contact—e.g. in the surface of the epitaxial layer and/or in some plane within the epitaxial layer. Disposition of such a contact within a surrounding isolation region improves utilization of an available area of a pixel array. For example, regions in a pixel array architecture which were previously designed to only provide crosstalk isolation may be adapted to further provide a path for drawing current from a substrate for the pixel array.

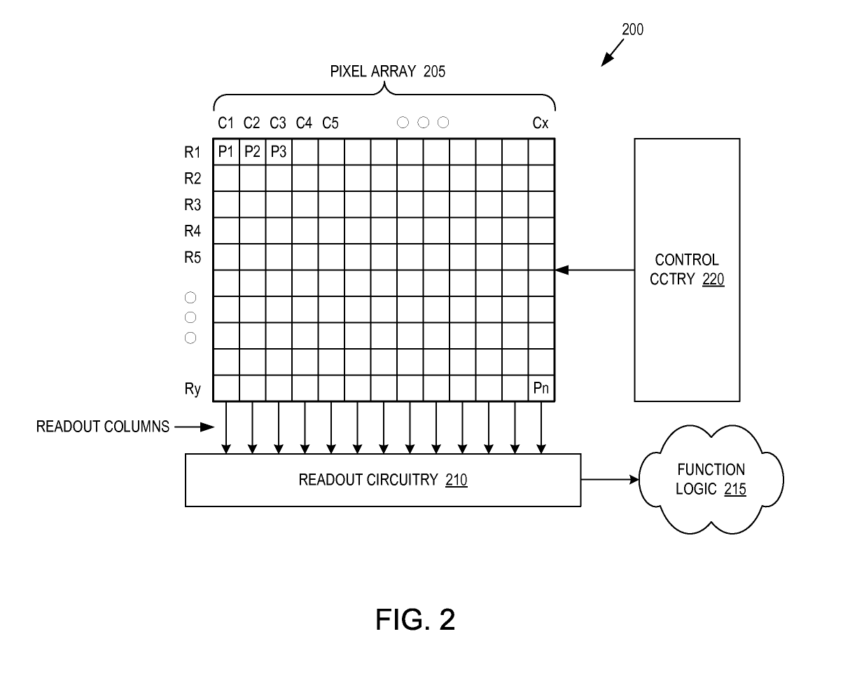

FIG. 2 is a block diagram illustrating select elements of an imaging system 200, in accordance with one embodiment. The illustrated embodiment of imaging system 200 includes a pixel array 205, readout circuitry 210, function logic 215, and control circuitry 220.

Pixel array 205 may include a two-dimensional (“2D”) array of illuminated imaging sensors or pixels (e.g., pixels P1, P2 . . . , Pn). In one embodiment, each pixel is a complementary metal-oxide-semiconductor (“CMOS”) imaging pixel. As illustrated, each pixel may be arranged into a row (e.g., rows R1 to Ry) and a column (e.g., column C1 to Cx) to acquire image data of a person, place, or object, which may then be used to render a 2D image of the person, place, or object.

After each pixel has acquired its image data or image charge, the image data may be readout by readout circuitry 210 and transferred to function logic 215. Readout circuitry 210 may include amplification circuitry, analog-to-digital (“ADC”) conversion circuitry, or otherwise. Function logic 215 may simply store the image data or even manipulate the image data by applying post image effects (e.g., crop, rotate, remove red eye, adjust brightness, adjust contrast, or otherwise). In one embodiment, readout circuitry 210 may readout a row of image data at a time along readout column lines (illustrated) or may readout the image data using a variety of other techniques (not illustrated), such as a serial readout or a full parallel readout of all pixels simultaneously.

Control circuitry 220 may be coupled to pixel array 205 to control operational characteristic of pixel array 205. For example, control circuitry 220 may generate a shutter signal for controlling image acquisition. In one embodiment, the shutter signal is a global shutter signal for simultaneously enabling all pixels within pixel array 205 to simultaneously capture their respective image data during a single acquisition window. In an alternative embodiment, the shutter signal is a rolling shutter signal whereby each row, column, or group of pixels is sequentially enabled during consecutive acquisition windows.

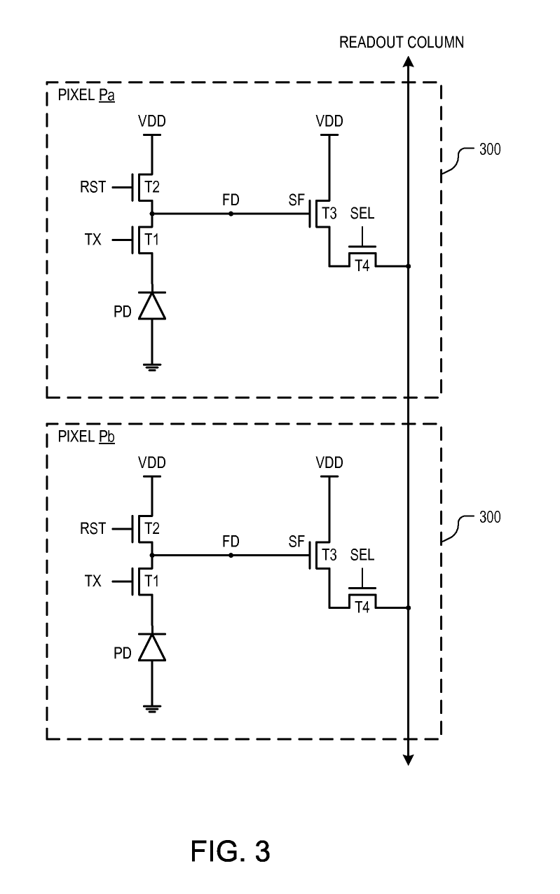

FIG. 3 is a circuit diagram illustrating pixel circuitry 300 of two four-transistor (“4T”) pixels within a pixel array, in accordance with one embodiment. Pixel circuitry 300 is an illustrative possible pixel circuitry architecture for implementing each pixel within such a pixel array. However, it should be appreciated that certain embodiments are not limited to 4T pixel architectures; rather, one of ordinary skill in the art having the benefit of the instant disclosure will understand that the present teachings are also applicable to 3T designs, 5T designs, and various other pixel architectures.

In FIG. 3, pixels Pa and Pb are arranged in two rows and one column. Pixels Pa and Pb may, for example, reside in a pixel array having some or all of the features of pixel array 200. The illustrated embodiment of each pixel circuitry 300 includes a photodiode PD, a transfer transistor T1, a reset transistor T2, a source-follower (“SF”) transistor T3 and a select transistor T4. During operation, transfer transistor T1 receives a transfer signal TX, which transfers the charge accumulated in photodiode PD to a floating diffusion node FD. In one embodiment, floating diffusion node FD may be coupled to a storage capacitor (not shown) for temporarily storing image charges.

Reset transistor T2 may be coupled between a power rail VDD and the floating diffusion node FD to reset the pixel (e.g., discharge or charge the FD and the PD to a preset voltage) under control of a reset signal RST. The floating diffusion node FD may be coupled to control the gate of SF transistor T3. SF transistor T3 may be coupled between the power rail VDD and select transistor T4. SF transistor T3 operates as a source-follower providing a high impedance connection to the floating diffusion FD. Finally, select transistor T4 may selectively couple the output of pixel circuitry 300 to the readout column line under control of a select signal SEL.

In one embodiment, the TX signal, the RST signal, and the SEL signal are generated by control circuitry 320. In an embodiment where pixel array 305 operates with a global shutter, the global shutter signal may be coupled to the gate of each transfer transistor T1 in the entire pixel array 305 to simultaneously commence charge transfer from each pixel's photodiode PD. Alternatively, rolling shutter signals may be applied to groups of transfer transistors T1.

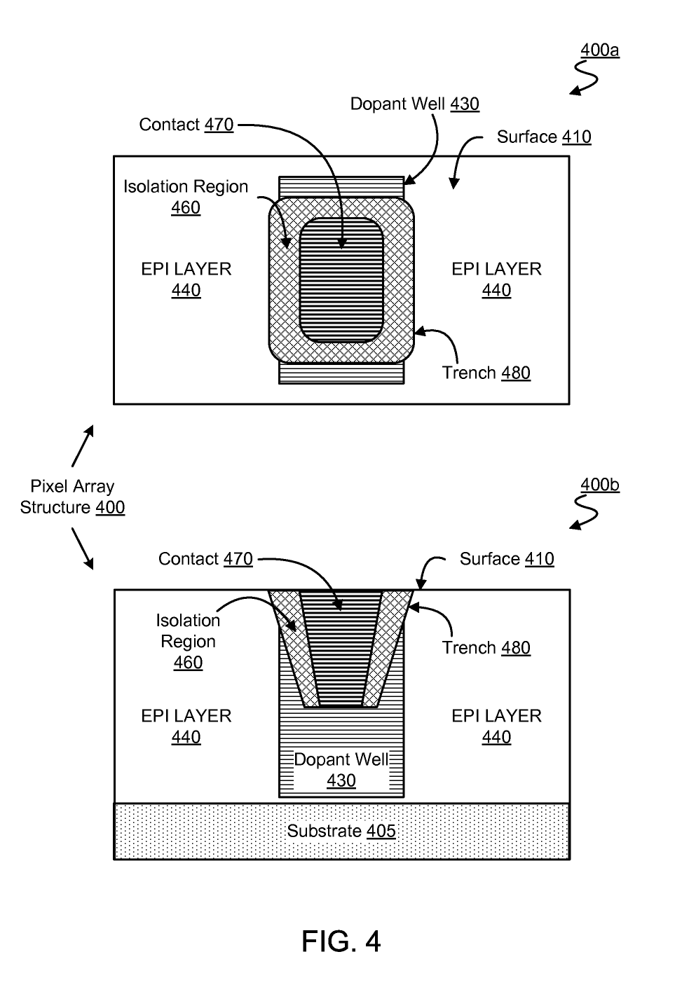

FIG. 4 shows both a surface elevation 400a and a cross-sectional view 400b illustrating select elements of a pixel array structure 400 according to an embodiment. Pixel array structure 400 may be located in a pixel array having some or all of the features of pixel array 205, for example.

A structure including features such as those discussed herein with respect to pixel array structure 400 may, for example, be included in a periphery of a pixel array for isolation which reduces electrical crosstalk between the pixel array and other circuitry proximate thereto. Alternatively or in addition, such a structure may be included within the interior of a pixel array —e.g. between respective components of different pixels for reducing electrical crosstalk between such pixels. Alternatively or in addition, such a structure may be included between different components in a single pixel of the pixel array—e.g. for reducing electrical crosstalk internal to the single pixel.

Pixel array structure 400 may include a substrate 405 and an epitaxial layer 440 adjoining substrate 405. A dopant well 430 and an isolation region 460 may be disposed within epitaxial layer 440. By way of illustration and not limitation, isolation region 460 may be deposited in a trench 480 which has been etched or otherwise formed in a surface 410 of epitaxial layer 440. Dopant well 430 may be disposed, for example, at least between the trench 480 and substrate 405. Isolation region 460 may further extend from surface 410 of epitaxial layer 440 in a direction toward substrate 405. In an embodiment, at least some portion of dopant well 430 is disposed between isolation region 460 and substrate 405.

In certain embodiments, a portion of dopant well 430 may extend beyond some or all of isolation region 460 in a direction parallel to surface 410, although certain embodiments are not limited in this regard. By way of illustration and not limitation, a portion of dopant well 430 —e.g. one or more interior walls of dopant well 430—may form a hollow or other depression into which some or all of isolation region 460 may be disposed. A portion of dopant well 430 may surround a portion of isolation region 460—e.g. in the surface of epitaxial layer 440 and/or in some plane within epitaxial layer 440.

Image sensing device 400 may also include a contact 470 which is also disposed in epitaxial layer 440. For example, contact 470 may be deposited in the same trench 480 in which isolation region 460 is disposed—where isolation region 460 surrounds contact 470 in trench 480. In an embodiment, within some plane of epitaxial layer 440, a portion of isolation region 460 may surround a portion of contact 470. By way of illustration and not limitation, contact 470 may extend from surface 410 in a direction toward substrate 405. A portion of isolation region 460—e.g. one or more interior sidewalls of isolation region 460—may, for example, form a cavity which extends through isolation region 460 and which provides access to dopant well 430. Contact 470 may be disposed within such a cavity, providing a conductive channel between dopant well 430 and surface 410. Contact channel 470 may be connected to, or available at surface 410 for connection to, a trace or other structure leading to a current sink (not shown), resulting in improved conductivity in substrate 405

In one embodiment, dopant well 430 is a p-type doped well which, for example, prevents direct interface between isolation region 460 and an adjacent n-type doped photodiode (PD) region or other pixel structure (not shown). In such an embodiment, substrate 405 and epitaxial layer 440 may also be p-type doped to respective degrees—e.g. for operation with such an n-type doped PD region. However, it should be appreciated that the conductivity types of all such elements may, in certain embodiments, be swapped—for example, where substrate 405 is n-type doped, epitaxial layer 440 is n-type doped, an adjoining PD region is p-type doped, and dopant well 430 is n-type doped.

In FIG. 4, isolation region 460 and contact 470 are each shown as forming a generally rectilinear area in surface 410 and forming a generally tapered cross-sectional profile in epitaxial layer 440. However, one of ordinary skill would appreciate from the discussion herein that any of a variety of alternative areas in surface 410 and/or any of a variety of alternative profiles in epitaxial layer 440—consistent with other features of embodiments described herein—may be variously formed by either or both of isolation region 460 and contact 470. For example, isolation region 460 and contact 470 may each form any of a variety of topologies wherein at least some portion of isolation region 460 surrounds a portion of contact 470. Similarly, it is understood that the size and/or shape of dopant well 430 may vary, in different embodiments—e.g. according to doping techniques used to dispose dopant well 430 in epitaxial layer 440.

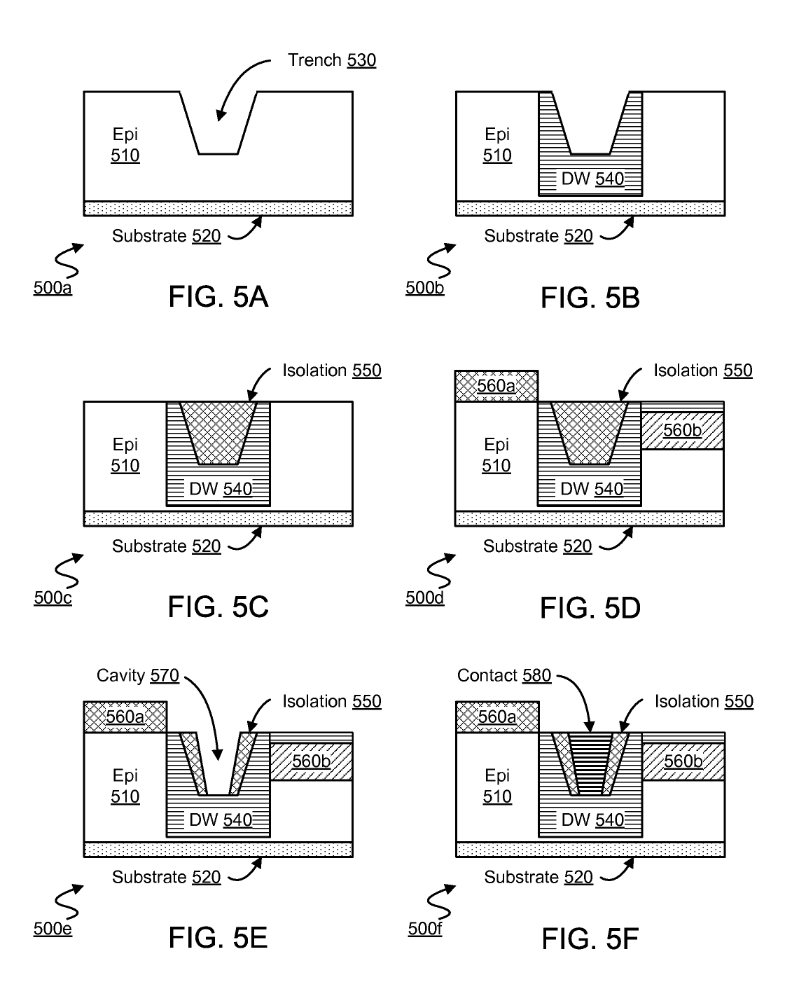

FIGS. 5A through 5F show, respectively, cross-sectional views 500a through 500f which each illustrate select elements of a fabrication process according to an embodiment. Views 500a through 500f may, for example, illustrate some or all of the features of a process to fabricate pixel array structure 400.

The fabrication process may, in an embodiment, include creating structures in and/or on a sheet of semiconductor materials which includes an epitaxial layer 510 and an adjoining substrate 520. The substrate 520 may be more heavily doped than the adjoining epitaxial layer 510—e.g. as with substrate 105 and epi layer 140.

As shown in view 500a, a trench 530 may be formed in a surface of epitaxial layer 530—e.g. where the trench 530 extends toward substrate 520. The particular location and/or depth of trench 530 may be implementation specific, e.g. depending upon the particular architecture of a desired pixel array. A trench depth may, for example, be around 300 to 400 nm deep (depending on the technology used to form the trench), or may be less than 400 nm. Certain embodiments are not limited with respect to techniques used to form trench 530, which may be formed, for example, according to any of a variety of known etching processes (such as a wet or dry etch process). Such processes may include, for example, etching processes which are used to form conventional deep trench and/or shallow trench structures such as that for the location of STI 160.

As shown in view 500b of FIG. 5B, a doping operation may be performed to dispose a dopant well DW 540 at least in an area of epitaxial layer 510 which is between trench 530 and substrate 520. For example, a high energy implant of boron or other suitable dopant into and through trench 530 may result in formation of a well beneath—and in certain embodiments, to the sides of—trench 530. However, certain embodiments are not limited with respect to techniques used to form DW 540, which may be formed, for example, according to any of a variety of known doping processes such as those used to create a dopant well such as p-well 130. In an embodiment, DW 540 extends sufficiently close to substrate 520 to aid in the conducting of current from substrate 520.

As shown in view 500c, of FIG. 5C, an isolation 550 may be filled into trench 530—e.g. where the isolation 550 is to be further formed later to accommodate a contact material, according to an embodiment. Isolation 550 may include a dielectric material such as silicon dioxide and/or any of a variety of other isolating materials for limiting electrical crosstalk. Techniques for initially filling trench 530 with an isolating material, as shown in view 500c, may be performed, for example, according to any of a variety of known processes used, for example, to create STI 160. However, it is understood that certain operations to subsequently form other structures of isolation 550—e.g. a cavity 570 which extends through isolation 550—may be distinguished from current techniques.

As shown in view 500d of FIG. 5D, one or more other pixel array elements may be variously disposed in and/or on epitaxial layer 510—e.g. including one or more elements which, but for various features of certain embodiments, would otherwise affect pixel array operation with electrical cross-talk. For the purpose of illustrating features of one embodiment, a transfer gate 560a is shown in view 500d as disposed on epitaxial layer 510 and a photosensitive (e.g. photodiode) region 560b is shown in view 500d as disposed in epitaxial layer 510. However, it is understood that any of a variety of additional or alternative pixel array elements, for which and/or from which isolation 550 provides cross-talk reduction, may be disposed in epitaxial layer 510. The particular type of such additional pixel array elements, and/or their respective placement in relation to isolation 550, is not limiting on certain embodiments. It is understood that disposition of any such additional pixel array element in or on epitaxial layer 510 may be performed earlier or later in the fabrication process, according to various embodiments.

As shown in view 500e of FIG. 5E, one or more additional structures of isolation 550 may be formed—e.g. in order to provide access to a portion of DW 540 which is disposed between isolation 550 and substrate 520. In an embodiment, an interior portion of isolation 550 may be etched away to form a cavity 570 extending through isolation 550 to provide access to DW 540. For example, cavity 570 may allow for contact material to be disposed therein—e.g. for providing a conductive channel between DW 540 and a surface of epitaxial layer 510.

The etching of cavity 570 may be coordinated, for example, with the etching of one or more other structures (not shown) of the pixel array architecture—e.g. an oxide structure. In an embodiment, the etching of cavity 570 may be deeper than the etching of such other structure(s). For example, another, comparatively shallow silicon dioxide or other dielectric structure (not shown) disposed on epitaxial layer 510 may need to be etched through only to the surface of epitaxial layer 510. In such an embodiment, etching of cavity 570 may be achieved with an etchant which is tolerated by epitaxial layer 510—wherein over-etching through the comparatively shallow oxide dielectric structure may be avoided.

As shown in view 500f of FIG. 5F, a contact 580 may be disposed in trench 530—e.g. in cavity 570—to form a conductive channel between the surface of epitaxial layer 510 and a portion of DW 540 which is located between isolation 550 and substrate 520. In an embodiment, isolation 550 may surround contact 580 within trench 530. By way of illustration and not limitation, a metal may be laid down in cavity 570 during a metallization stage—e.g. a stage which disposes one or more additional metal structures (not shown) on epitaxial layer 510. Contact 580 may include, for example, copper, aluminum, an aluminum copper mixture, and/or any other material suitable for carrying a signal. It may be beneficial in certain embodiments to defer etching of cavity 570 to just prior to such a metallization stage—e.g. to prevent unnecessary filling of cavity 570 during some intermediary process before the metallization which forms contact 580. In certain alternate embodiments, contact 580 may include a doped polysilicon which, for example, exhibits some or all of the conductive properties of a doped polysilicon forming DW 540.

In one embodiment, DW 540 is a p-type doped well which, for example, prevents direct interface between isolation 550 and an n-type doped photosensitive region 560b or other such pixel structure. In such an embodiment, substrate 520 and epitaxial layer 510 may also be p-type doped to respective degrees—e.g. for operation with an n-type doped photosensitive region 560b. However, it should be appreciated that the conductivity types of all such elements may, in certain embodiments, be swapped—for example, where substrate 520 is n-type doped, epitaxial layer 510 is n-type doped, photosensitive region 560b is p-type doped, and DW 540 is n-type doped.

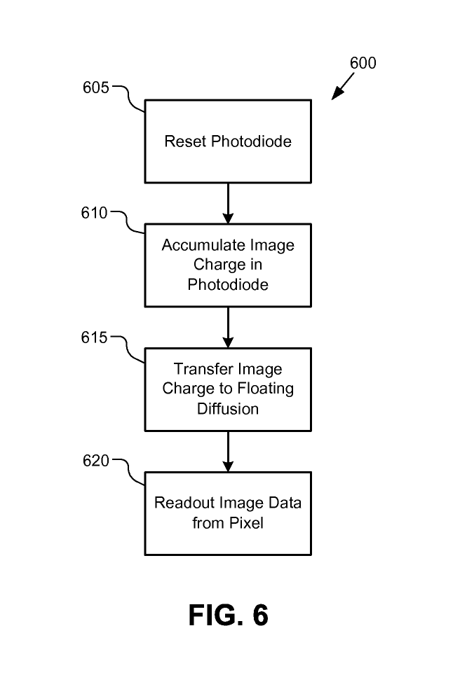

FIG. 6 is a flow chart illustrating a process 600 for operating BSI imaging pixel 300, in accordance with one embodiment. Process 600 illustrates the operation of a single pixel within pixel array 205; however, it should be appreciated that process 600 may be sequentially or concurrently executed by each pixel in pixel array 205 depending upon whether a rolling shutter or global shutter is used. The order in which some or all of the process blocks appear in process 600 should not be deemed limiting. Rather, one of ordinary skill in the art having the benefit of the present disclosure will understand that some of the process blocks may be executed in a variety of orders not illustrated.

In a process block 605, photodiode PD is reset. Resetting includes discharging or charging photodiode PD to a predetermined voltage potential, such as VDD. The reset is achieved by asserting both the RST signal to enable reset transistor T2 and asserting the TX signal to enable transfer transistor T1. Enabling T1 and T2 couples photodiode region PD and floating diffusion FD to power rail VDD.

Once reset, the RST signal and the TX signal are de-asserted to commence image acquisition by photodiode region 420 (process block 610). Light incident on the backside of imaging pixel 300 cause charge to accumulate within photodiode PD.

Once the image acquisition window has expired, the accumulated charge within photodiode PD may be transferred via transfer transistor T1 to floating diffusion FD by asserting the TX signal (process block 615). In the case of a global shutter, the global shutter signal is asserted simultaneously, as the TX signal, to all pixels within the pixel array (e.g. pixel array 205) during process block 615. This results in a global transfer of the image data accumulated by each pixel into the pixel's corresponding floating diffusion FD.

Once the image data is transferred, the TX signal is de-asserted to isolate floating diffusion FD from photodiode PD for readout. In a process block 620, the SEL signal is asserted to transfer the stored image data onto the readout column for output—e.g. to the function logic 215 via readout circuitry 210. It should be appreciated that readout may occur on a per row basis via column lines (illustrated), on a per column basis via row lines (not illustrated), on a per pixel basis (not illustrated), or by other logical groupings. Once the image data of all pixels has been readout, process 600 may return to process block 605 to prepare for the next image.

In one embodiment, other circuitry may include a storage capacitor coupled to the floating diffusion FD to temporarily store the image charge so that post image acquisition processing may be executed within each pixel prior to readout in process block 620. Additionally or alternatively, such other circuitry may include gain circuitry, ADC circuitry, or otherwise.

Techniques and architectures for providing conductivity in a pixel array are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A pixel array comprising:
a plurality of pixels disposed in or on an epitaxial layer having a trench formed in a surface thereof, the epitaxial layer adjoining a substrate, wherein the plurality of pixels includes:
a dopant well disposed within the epitaxial layer at least between the substrate and the trench;
an isolation region disposed within the trench; and
a contact disposed within the trench, wherein the isolation region surrounds the contact within the trench.

2. The pixel array of claim 1, wherein a portion of the isolation region forms a cavity extending through the isolation region, wherein the contact extends within the cavity from the dopant well to the surface of the epitaxial layer.

3. The pixel array of claim 1, wherein the dopant well extends beyond an exterior boundary of the isolation region in a direction parallel to the surface of the epitaxial layer.

4. The pixel array of claim 3, wherein the dopant well surrounds the isolation region.

5. The pixel array of claim 1, wherein the contact is disposed between respective elements of two pixels of the pixel array.

6. The pixel array of claim 1, wherein the contact is disposed between a first element of a first pixel in the pixel array and a second element of the first pixel.

7. The pixel array of claim 1, wherein the contact includes a doped polysilicon.

8. The pixel array of claim 1, wherein the pixel array includes a CMOS pixel array.

9. An image sensing device comprising:
a substrate;
an epitaxial layer adjoining the substrate, wherein a trench is formed in a surface of the epitaxial layer;
a pixel array including a plurality of pixels disposed in or on the epitaxial layer, the pixel array including:
a dopant well disposed within the epitaxial layer at least between the substrate and the trench;
an isolation region disposed within the trench; and
a contact disposed within the trench, wherein the isolation region surrounds the contact within the trench; and
control circuitry coupled to the pixel array to control an acquisition of an image by the pixel array.

10. The image sensing device of claim 9, wherein a portion of the isolation region forms a cavity extending through the isolation region, wherein the contact extends within the cavity from the dopant well to the surface of the epitaxial layer.

11. The image sensing device of claim 9, wherein the dopant well extends beyond an exterior boundary of the isolation region in a direction parallel to the surface of the epitaxial layer.

12. The image sensing device of claim 11, wherein a portion of the dopant well surrounds a portion of the isolation region.

13. The image sensing device of claim 9, wherein the contact is disposed between respective elements of two pixels of the pixel array.

14. The image sensing device of claim 9, wherein the contact is disposed between a first element of a first pixel in the pixel array and a second element of the first pixel.

15. The image sensing device of claim 9, wherein the contact includes a doped polysilicon.

16. The image sensing device of claim 9, wherein the pixel array includes a CMOS pixel array.

17. A method comprising:
etching a trench in a surface of an epitaxial layer for a pixel array, wherein a substrate adjoins the epitaxial layer;
performing a doping to form a dopant well within the epitaxial layer at least between the substrate and the trench;
depositing a dielectric material within the trench;
etching the dielectric material to create an isolation region, wherein a portion of the isolation region forms a cavity extending through the isolation region; and
depositing a contact within the cavity.

18. The method of claim 17, wherein the contact is deposited between respective elements of two pixels of the pixel array.

19. The method of claim 17, wherein the contact is deposited between a first element of a first pixel in the pixel array and a second element of the first pixel.

20. The method of claim 17, wherein the contact includes a doped polysilicon.
